(19) United States
(12) Patent Application Publication
(10) Pub. No.: US 2008/0036002 A1
(43) Pub. Date: Feb. 14, 2008

(54) Semiconductor device and method of fabricating semiconductor device

(75) Inventor: Koichi Kishiro, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/812,434

(22) Filed: Jun. 19, 2007

(30) Foreign Application Priority Data
Aug. 9, 2006 (JP) JP2006-216518

(51) Int. Cl. H01L 21/76; H01L 27/12

(52) U.S. Cl. 257/350; 438/149; 257/E29.001; 257/E21.704

(57) ABSTRACT

Surge current, which flows-in from an exterior due to ESD or the like, is prevented from directly flowing-into a supporting substrate. A semiconductor device has: an element-isolating insulating film sectioning an SOI layer into an active region and a field region; a resistance element formed at the field region; one or more layers of an interlayer insulating films formed on an SOI substrate; a ground terminal for a substrate contact formed on the interlayer insulating film; a substrate contact passing through the element-isolating insulating film and a BOX layer, and electrically connected to the supporting substrate; a first wire electrically connecting the substrate contact and the resistance element; and a second wire electrically connecting the resistance element and the ground terminal for a substrate contact.

### CROSS-REFERENCE TO RELATED APPLICATION

This application claims priority under 35 USC 119 from Japanese Patent Application No. 2006-216518, the disclosure of which is incorporated by reference herein.

### BACKGROUND OF THE INVENTION

1. Field of the Invention

The present invention relates to a semiconductor device using an SOI (Silicon on Insulator) substrate and a method of fabricating a semiconductor device, and in particular, relates to a semiconductor device, in which the potential of a supporting substrate at an SOI substrate can be fixed, and a method of fabricating a semiconductor device.

2. Description of the Related Art

Conventionally, there is a structure in which a contact (hereinafter called a substrate contact), which passes through a silicon thin film (hereinafter called SOI layer) and through a buried oxide film (hereinafter called BOX layer) at an SOI substrate, and electrically connects to a supporting substrate, is formed. Further, by using this substrate contact, the potential of the supporting substrate is fixed via a wire from the SOI substrate surface side (see, for example, Japanese Patent Application Laid-Open (JP-A) No. 2004-319853).

However, in a structure which provides substrate contacts, in post-processes after the wafer process (hereinafter abbreviated as WP) which forms the semiconductor elements or the like, and at the time of actual use, surge current which flows-in from the exterior due to electrostatic discharge (ESD) or the like directly flows into the supporting substrate. As a result, the potential difference between the supporting substrate and the semiconductor element rises steeply, and there is the problem that a high electric field is applied to the BOX layer between the supporting substrate and the semiconductor element. There are cases in which such a problem leads to poor resistance of the BOX layer in the internal circuit or fluctuations in the characteristic of the semiconductor element.

### SUMMARY OF THE INVENTION

In order to overcome the above-described problems, a semiconductor device in accordance with the present invention has: an SOI substrate including a supporting substrate, an insulating film on the supporting substrate, and a semiconductor layer on the insulating film; an element-isolating insulating film sectioning the semiconductor layer into an element forming region and an element isolating region; a resistance element formed at the element isolating region; one or more layers of an interlayer insulating film formed on the SOI substrate; a first terminal formed on the interlayer insulating film; a substrate contact passing through the element-isolating insulating film and the insulating film, and electrically connected to the supporting substrate; a first wire electrically connecting the substrate contact and the resistance element; and a second wire electrically connecting the resistance element and the first terminal.

Further, a semiconductor device in accordance with the present invention has: an SOI substrate including a supporting substrate, an insulating film on the supporting substrate, and a semiconductor layer on the insulating film; an element-isolating insulating film sectioning the semiconductor layer into an element forming region and an element isolating region; one or more layers of an interlayer insulating film formed on the SOI substrate; a first terminal formed on the interlayer insulating film; a substrate contact passing through the element-isolating insulating film and the insulating film, and electrically connected to the supporting substrate, a junction resistance of the substrate contact and the supporting substrate being greater than or equal to 2 kΩ; a first wire electrically connecting the substrate contact and the resistance element; and a second wire electrically connecting the resistance element and the first terminal.

A method of fabricating a semiconductor device in accordance with the present invention includes: preparing an SOI substrate which includes a supporting substrate, an insulating film on the supporting substrate, and a semiconductor layer on the insulating film; sectioning the semiconductor layer into an element forming region and an element isolating region by forming an element-isolating insulating film at the semiconductor layer; forming a first transistor at the element forming region; forming a resistance element at the element isolating region; forming an interlayer insulating film on the semiconductor layer at which the first transistor and the resistance element are formed; forming a substrate contact which passes through the interlayer insulating film, the element-isolating insulating film and the insulating film, and which is electrically connected to the supporting substrate; and respectively forming a first wire, which electrically connects the substrate contact and the resistance element, and a second wire, which electrically connects the resistance element and the first transistor.

In accordance with the present invention, there can be realized a semiconductor device and a method of fabricating a semiconductor device which can prevent surge current, which flows-in from the exterior due to ESD or the like, from directly flowing-into the supporting substrate.

### BRIEF DESCRIPTION OF THE DRAWINGS

Preferred exemplary embodiments of the present invention will be described in detail based on the following figures, wherein:

FIG. 1 is a cross-sectional view showing a layer structure of a semiconductor device in accordance with a first exemplary embodiment of the present invention;

FIG. 2 is a plan view showing the positional relationship between a resistance element and a ground terminal for a substrate contact in the first exemplary embodiment of the present invention;

FIG. 3A is a process drawing showing a fabricating process of the semiconductor device in accordance with the first exemplary embodiment of the present invention;

FIG. 3B is a process drawing showing a fabricating process of the semiconductor device in accordance with the first exemplary embodiment of the present invention;

FIG. 3C is a process drawing showing a fabricating process of the semiconductor device in accordance with the first exemplary embodiment of the present invention;

FIG. 3D is a process drawing showing a fabricating process of the semiconductor device in accordance with the first exemplary embodiment of the present invention;

FIG. 3E is a process drawing showing a fabricating process of the semiconductor device in accordance with the first exemplary embodiment of the present invention;

FIG. 4 is a diagram showing an example of a schematic circuit diagram of the semiconductor device in accordance with the first exemplary embodiment of the present invention;

FIG. 5 is a cross-sectional view showing another layer structure of the semiconductor device in accordance with the first exemplary embodiment of the present invention;

FIG. 6 is a cross-sectional view showing a layer structure of a semiconductor device in accordance with a second exemplary embodiment of the present invention;

FIG. 7A is a process drawing showing a fabricating process of the semiconductor device in accordance with the second exemplary embodiment of the present invention;

FIG. 7B is a process drawing showing a fabricating process of the semiconductor device in accordance with the second exemplary embodiment of the present invention;

FIG. 7C is a process drawing showing a fabricating process of the semiconductor device in accordance with the second exemplary embodiment of the present invention;

FIG. 7D is a process drawing showing a fabricating process of the semiconductor device in accordance with the second exemplary embodiment of the present invention;

FIG. 7E is a process drawing showing a fabricating process of the semiconductor device in accordance with the second exemplary embodiment of the present invention;

FIG. 8 is a cross-sectional view showing a layer structure of a semiconductor device in accordance with a third exemplary embodiment of the present invention; and

FIG. 9 is a process drawing showing a fabricating process of the semiconductor device in accordance with the third exemplary embodiment of the present invention.

### DETAILED DESCRIPTION OF THE INVENTION

Exemplary embodiments for implementing the present invention will be described hereinafter in detail together with the drawings.

### First Exemplary Embodiment

First, a first exemplary embodiment in accordance with the present invention will be described in detail by using the drawings.

### (Structure)

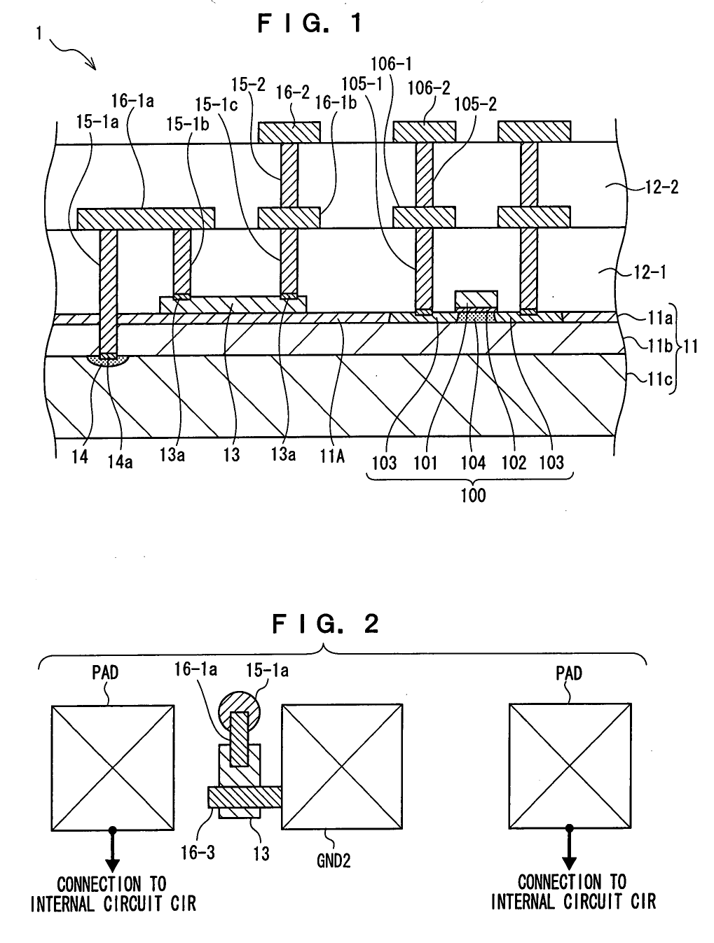

FIG. 1 is a cross-sectional view showing a layer structure of a semiconductor device 1 in accordance with the present exemplary embodiment. As shown in FIG. 1, the semiconductor device 1 has an SOI substrate 11, interlayer insulating films 12-1 and 12-2, a resistance element 13, a substrate contact 15-1a, via wires 15-1b through 15-2, lowermost layer metal wires 16-1a and 16-1b, an upper layer metal wire 16-2, a transistor 100, via wires 105-1 and 105-2, lowermost layer metal wires 106-1, and upper layer metal wires 106-2.

In this structure, the SOI substrate 11 has a supporting substrate 11c, a BOX layer 11b, and an SOI layer 11a.

The supporting substrate 11c is a bulk silicon substrate which is doped such that, for example, the p-type impurities are a concentration of about 1×10¹⁵/cm³ for example. The substrate resistance is about 8 to 22Ω (ohms) for example. However, the present exemplary embodiment is not limited to the same, and any of various semiconductor substrates (including compound semiconductors) can be used.

The BOX layer 11b is a silicon oxide film having a film thickness of about 1000 to 2000 Å (angstroms) for example. However, the present exemplary embodiment is not limited to the same, and any of various insulating films can be used.

The SOI layer 11a is a silicon thin film which is doped such that, for example, the concentration of the p-type impurities (e.g., boron ions) is a relatively low concentration of about 1 to 3×10¹⁵/cm³ for example. The film thickness thereof can be made to be about 200 to 1000 Å for example. Note that a non-doped silicon thin film also can be used as the SOI layer 11c. The impurity concentration in this case is the same concentration as that of the supporting substrate 11a, e.g., about 1×10¹⁵/cm³.

An element-isolating insulating film 11A is formed at the SOI layer 11a. The SOI layer 11a is sectioned into an element forming region (also called active region) and an element isolating region (also called field region) by the element-isolating insulating film 11A. The element-isolating insulating film 11A can be formed, for example, by using LOCOS (Local Oxidation of Silicon), STI (Shallow Trench Isolation), or the like.

For example, the transistor 100 is formed as a semiconductor element at the active region at the SOI layer 11a. The transistor 100 includes a pair of diffusion regions 103 formed at the active region, a body region 104 between the pair of diffusion regions 103, a gate insulating film 102 on the body region 104, and a gate electrode 101 on the gate insulating film 102. However, the semiconductor element in the present invention is not limited to the above-described transistor 100, and may be another element which is any of various semiconductor elements or capacitors or the like, such as a PN junction diode or the like.

The transistor 100 is electrically connected to the wires (the via wires 105-2, the upper layer metal wires 106-2, and the like which will be described later) which are formed at layers above the interlayer insulating film 12-1, via the lowermost layer metal wires 106-1 on the interlayer insulating film 12-1 and the via wires 105-1 which pass through the interlayer insulating film 12-1. The transistor 100 is further connected to a ground terminal (not shown) via these.

Further, the resistance element 13 is formed on the field region at the SOI layer 11a. A polysilicon film, in which impurities are doped to the extent that the desired specific resistance is obtained, can be used as the resistance element 13. However, the present invention is not limited to the same, and any of various resistance elements can be used. Moreover, the resistance value of the resistance element 13 is preferably greater than or equal to about 2 kΩ (kilo-ohms) for example.

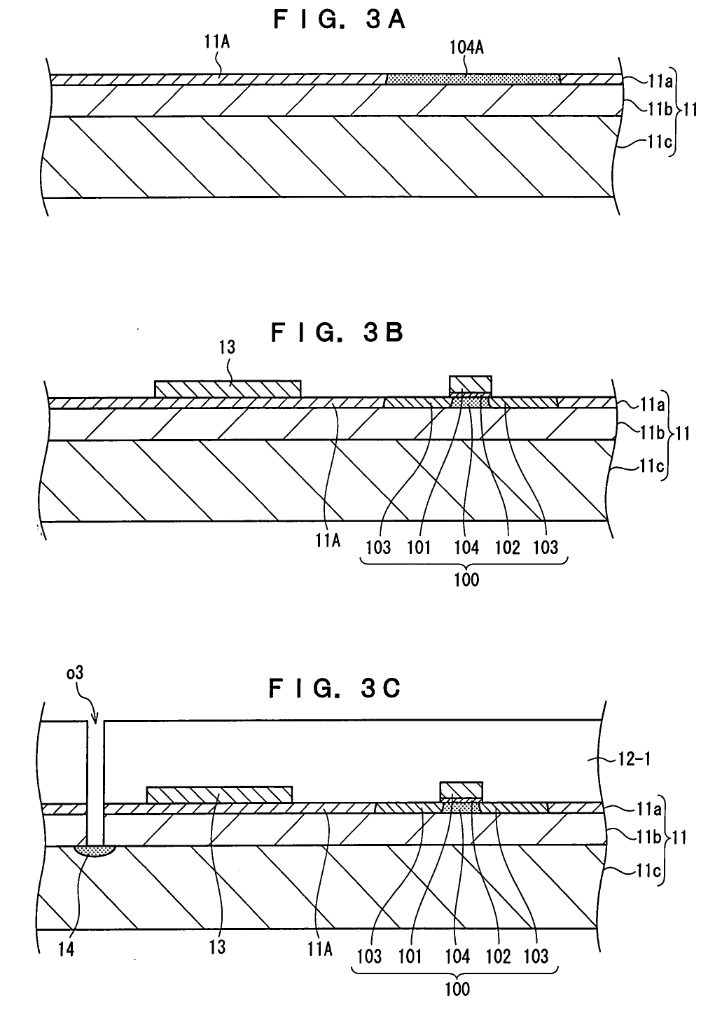

In the present exemplary embodiment, as shown in FIG. 2, it is preferable that the resistance element 13 be formed between a ground terminal GND2 for the substrate contact (hereinafter called ground terminal (first terminal) for the substrate contact) and another pad PAD which is adjacent thereto. In this way, there is no need to make great changes to the conventional layout. As a result, the increase in the manufacturing cost can be kept to a minimum. Note that the interlayer insulating films are not shown in FIG. 2 for clarity of explanation. Further, the ground terminal GND2 for the substrate contact is a terminal which is formed on the interlayer insulating film of the uppermost layer, and is electrically connected to the upper layer metal wire 16-2 in FIG. 1 via an uppermost layer metal wire 16-3 and an unillustrated via wire.

One end of the resistance element 13 is electrically connected to the supporting substrate 11c, via the lowermost layer metal wire 16-1a on the interlayer insulating film 12-1, the via wire 15-1b which passes through the interlayer insulating film 12-1, and the substrate contact 15-1a which passes through from the interlayer insulating film 12-1 to the BOX layer 11b. The other end of the resistance element 13 is electrically connected to the wires (the via wire 15-2, the upper layer metal wire 16-2, and the like which will be described later) which are formed at layers above the interlayer insulating film 12-1, via the via wire 15-1c which passes through the interlayer insulating film 12-1 and the lowermost layer metal wire 16-1b on the interlayer insulating film 12-1. This other end of the resistance element 13 is further connected to a ground terminal for the substrate (not shown) via these.

The interlayer insulating film 12-1 is an insulating film for electrically isolating the SOI layer 11a, at which the transistor 100 and the resistance element 13 are formed, and the layers thereabove. For example, a silicon oxide film, a silicon nitride film, or the like can be used as this insulating film. Further, the film thickness thereof can be about 8000 Å for example.

The interlayer insulating film 12-2 is formed on the interlayer insulating film 12-1. In the same way as the interlayer insulating film 12-1, for example, a silicon oxide film, a silicon nitride film, or the like can be used as this insulating film. Further, the film thickness thereof can be about 8000 Å for example.

The lowermost layer metal wires 16-1a, 16-1b, and 106-1 which are formed on the interlayer insulating film 12-1, and the upper layer metal wires 16-2 and 106-2 which are formed on the interlayer insulating film 12-2, can respectively be, for example, a metal film of titanium (Ti), aluminum (Al), copper (Cu), or the like, or a metal film formed from an alloy thereof. Further, a conductor film, which is a titanium nitride (TiN) film or a titanium aluminum nitride (TiAlN) film, or the like, may be formed as an adhesion layer on the respective top and bottom surfaces of the metal wires 16-1a, 16-1b, 16-2, and 106-1 and 106-2.

The substrate contact 15-1a which passes through from the interlayer insulating film 12-1 to the BOX layer 11c, and the via wires 15-1b, 15-1c and 105-1 which pass through the interlayer insulating film 12-1, and the via wires 15-2 and 105-2 which pass through the interlayer insulating film 12-2, can be formed, for example, of a metal such as tungsten (W), copper (Cu), aluminum (Al) or the like, or of a polysilicon which is electrically conductive, or the like.

Note that, as needed, an interlayer insulating film, via wires, and upper layer/uppermost layer metal wires are respectively formed on the interlayer insulating film 12-2.

At the supporting substrate 11c, a diffusion region 14 is formed at the portion which is electrically connected to the substrate contact 15-1a. The diffusion region 14 is a region which is doped such that, for example, the p-type impurities (e.g., boron ions) are a concentration of about 1×10¹⁸/cm³ for example.

A silicide film 14a is formed at the connected portion of the diffusion region 14 and the substrate contact 15-1a. In this way, the connection resistance between the supporting substrate 11c and the substrate contact 15-1a is reduced. Similarly, a silicide film 13a may also be formed at the connected portion of the via wire 15-1b or 15-1c and the resistance element 13. Further, similarly, a silicide film may be formed also at the connected portion of the via wire 105-1 and the transistor 100.

### (Fabrication Method)

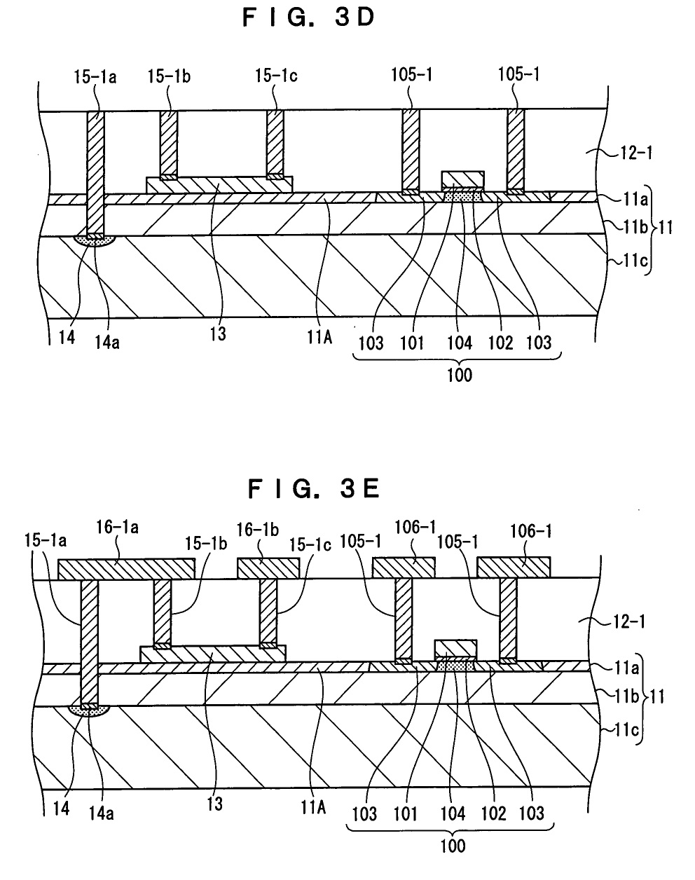

Next, a method of fabricating the semiconductor device 1 in accordance with the present exemplary embodiment will be described in detail by using the drawings. FIG. 3A through FIG. 3E are process drawings showing a method of fabricating the semiconductor device 1 in accordance with the present exemplary embodiment.

In the present fabrication method, first, the SOI substrate 11 is readied. Next, the element-isolating insulating film 11A is formed by using, for example, STI or LOCOS or the like, at the SOI layer 11a of the SOI substrate 11. In this way, the SOI layer 11a is sectioned into an active region and a field region 104A. Next, predetermined impurities (e.g., boron ions) are injected into the active region 104A at the SOI layer 11a, for the purpose of adjusting the threshold value. At this time, the impurity concentration can be made to be about 1 to 3×10¹⁵/cm³. In this way, as shown in FIG. 3A, the SOI layer 11a is sectioned into the field region, at which the element-isolating insulating film 11A is formed, and the active region 104A, in which impurities for threshold value adjustment are injected.

Next, by carrying out photolithography and ion injection, the pair of diffusion regions 103 which function as a source and a drain are formed in the active region 104A. Note that the impurity concentration can be made to be about 1×10¹⁸/cm³ for example. Further, the active region 104A which remains between the diffusion regions 103 becomes the body region 104. Next, by thermally oxidizing the surface of the SOI substrate 11, a silicon oxide film of a film thickness of about 10 nm for example is formed on the surface of the active region 104A. Then, a polysilicon film, which is electrically conductive and has a film thickness of about 500 nm for example, is formed on the entire SOI layer 11a by using CVD or sputtering for example. Then, by patterning the polysilicon film and the silicon oxide film by carrying out photolithography and etching for example, the gate insulating film 102 and the gate electrode 101 are formed on the body region 104 at the active region 104A, and the resistance element 13 which is formed from the polysilicon film is formed at a portion on the element-isolating insulating film 11A which is the field region. In this way, as shown in FIG. 3B, the transistor 100 is formed as the semiconductor element at the active region 104A, and the resistance element 13 is formed on the element-isolating insulating film 11A.

Note that this explanation gives an example of a case in which the gate electrode 101 and the resistance element 13 are formed simultaneously by forming the polysilicon film which is electrically conductive and patterning it. However, the present invention is not limited to the same. Namely, for example, instead of the polysilicon film, a non-doped polysilicon film is formed for example, and after this polysilicon film is patterned into the shapes of the gate electrode 101 and the resistance element 13, predetermined impurities are respectively doped therein to desired impurity concentrations. In this way, there can be a structure in which the gate electrode 101 and the resistance element 13 are formed respectively.

Next, the interlayer insulating film 12-1, which is formed from a silicon oxide film and is a film thickness of about 8000 Å for example, is formed on the entire top surface of the SOI layer 11a including the transistor 100 by CVD for example. Then, an opening o3, which passes through from the interlayer insulating film 12-1 through the BOX layer 11b and exposes the supporting substrate 11c, is formed by carrying out photolithography and etching. Next, by injecting predetermined impurities (e.g., boron ions) into the supporting substrate 11c which is exposed from the opening o3 by using the interlayer insulating film 12-1 as a mask, the diffusion region 14 is formed at the contact portion of the supporting substrate 11c as shown in FIG. 3C. At this time, the impurity concentration can be made to be about 1×10¹⁸/cm³ for example.

Next, by carrying out photolithography and etching, openings o4, which expose the diffusion regions 103 at the transistor 100, and the openings o4, which expose both ends on the resistance element 13, are formed in the interlayer insulating film 12-1. Then, by filling a conductor such as tungsten (W) or the like for example into the openings o3 and o4 of the interlayer insulating film 12-1 by using sputtering for example, the substrate contact 15-1a and the via wires 15-1b, 15-1c and 105-1 are formed as shown in FIG. 3D. At this time, the surface of the supporting substrate 11c which is exposed by the openings o3 and the surface of the resistance element 13 and the surface of the diffusion region 103 which are exposed from the openings o4 may respectively be salicided, before the substrate contact 15-1a and the via wires 15-1b, 15-1c and 105-1 are formed.

Next, after a single-layer or multilayer metal film is accumulated on the interlayer insulating film 12-1, by patterning it by photolithography and etching, the lowermost layer metal wires 16-1a, 16-1b and 106-1 are formed on the interlayer insulating film 12-1 as shown in FIG. 3E.

Thereafter, one or more layers of the layers formed from the upper layer interlayer insulating film 12-2, the via wires 15-2 and 105-2, and the upper layer metal wires 16-2 and 106-1 are formed as needed. In this way, the semiconductor device 1 in accordance with the present exemplary embodiment, such as shown in FIG. 1, is fabricated.

As described above, the semiconductor device 1 in accordance with the present exemplary embodiment has: the SOI substrate 11 which includes the supporting substrate 11c, the insulating film (BOX layer 11b) on the supporting substrate 11c, and the semiconductor layer (SOI layer 11a) on the insulating film (BOX layer 11b); the element-isolating insulating film 11A which sections the semiconductor layer (SOI layer 11a) into the element forming region (active region 104A) and the element isolating region (field region); the resistance element 13 formed at the element isolating region (field region); one or more layers of the interlayer insulating film (12-1 and/or 12-2) formed on the SOI substrate 11; the first terminal (the ground terminal GND2 for the substrate contact) formed on the interlayer insulating film (12-1 and/or 12-2); the substrate contact 15-1a which passes through the element-isolating insulating film 11A and the insulating film (BOX layer 11b) and is electrically connected to the supporting substrate 11c; the first wires (lowermost layer metal wire 16-1a and via wire 15-1b) which electrically connect the substrate contact 15-1a and the resistance element 13; and the second wires (via wire 15-1c, lowermost layer metal wire 16-1b, via wire 15-2, upper layer metal wire 16-2) which electrically connect the resistance element 13 and the first terminal (the ground terminal GND2 for the substrate contact).

In this way, by inserting the resistance element 13 between the supporting substrate 11c and the wire layer of the upper layer (e.g., the ground terminal GND2 for the substrate contact (see FIG. 2)), the time constant of the circuit which is parasitic between the supporting substrate 11c and the metal layer of the upper layer becomes large. Note that this time constant is determined mainly by the resistance value of the resistance element 13 which is inserted. In this way, surge current, which flows-in from the exterior due to ESD or the like, can be prevented from directly flowing-in to the supporting substrate 11c. As a result, it is possible to avoid the potential of the supporting substrate 11c steeply rising and a high electric field being applied to the BOX layer between the supporting substrate 11c and the semiconductor element (the transistor 100), and poor resistance of the BOX layer in the internal circuit and fluctuations in the characteristic of the semiconductor element can be prevented.

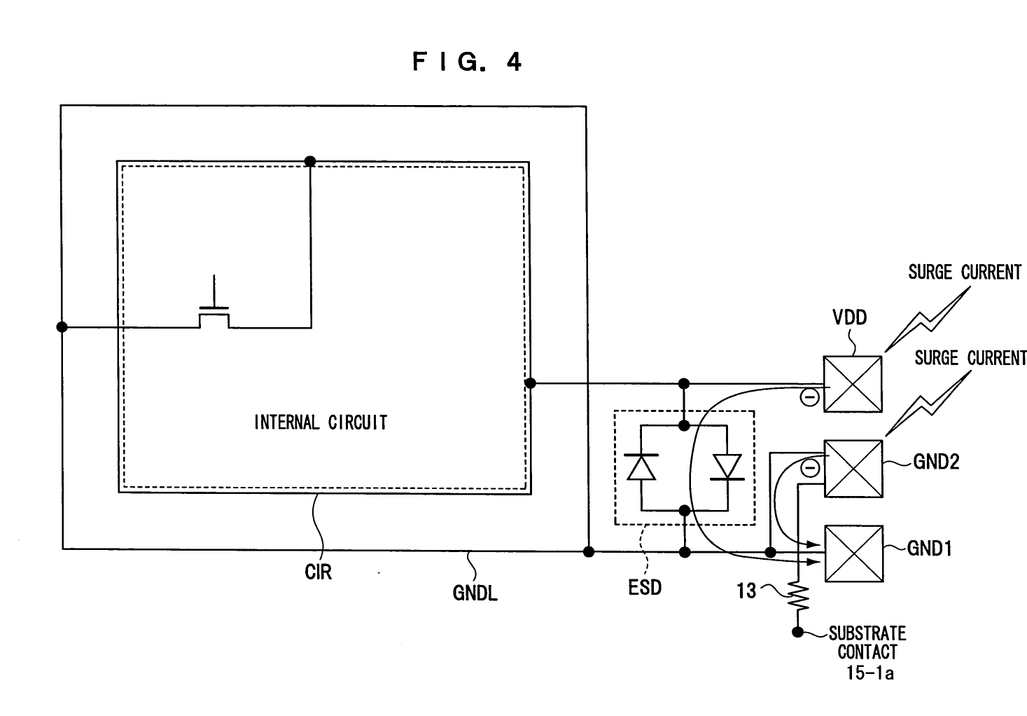

In a general semiconductor device, there are cases in which a protecting circuit ESD is provided with respect to surge current which flows-in from the exterior due to ESD or the like. In such cases, as shown in FIG. 4, the protecting circuit ESD is provided between a power source terminal VDD (third terminal) for an internal circuit CIR and a ground terminal GND1 (second terminal). At this time, from the standpoint of design, there are cases in which the ground terminal GND2 for the substrate contact and the ground terminal GND1 are electrically connected by ground line GNDL. However, when surge current, which flows-in to the power source terminal VDD or the ground terminal GND2 for the substrate contact, flows into the supporting substrate 11c via the substrate contact 15-1a before flowing-out to the ground terminal GND1 via the protecting circuit ESD, as a result, there are cases in which a high electric field is applied between the supporting substrate 11c and the semiconductor element (transistor 100), and poor resistance of the BOX layer 11b in the internal circuit CIR or fluctuations in the characteristic of the semiconductor element are caused. Thus, by inserting the resistance element 13 between the supporting substrate 11 and the wire layer of the upper layer (e.g., the ground terminal GND2 for the substrate contact (see FIG. 2 or FIG. 4)) as in the present exemplary embodiment, at the time when surge current flows-into the metal layer of the upper layer, it is possible for the surge current to either flow-out directly to the ground terminal GND1 or flow-out to the ground terminal GND1 via the protecting circuit CIR, before flowing-into the supporting substrate 11c. As a result, surge current flowing into the supporting substrate 11c can be prevented or decreased, and destruction of the BOX layer 11b can thereby be avoided.

Further, the substrate contact 15-1a such as described above must be formed in the WP. At this time, in the WP, there are cases in which a wire which electrically connects the substrate contact 15-1a and the ground end of the semiconductor element (the transistor 100) is formed. However, there are cases in which, after the formation of the wire which electrically connects the substrate contact 15-1a and the ground line of the semiconductor element, charges which are generated within the supporting substrate 11c flow into the semiconductor element via the substrate contact 15-1a and the wire. Therefore, when the transistor 100 is used as the semiconductor element for example, there are cases in which problems such as fluctuations in the transistor characteristic, deterioration of the gate insulating film, and the like are caused.

Several causes can be thought of as the causes why charges are generated in the WP, such as the stage bias which is applied in the CVD process or the etching process, the bias of the electrostatic chuck which is applied in order to attract the wafer to the stage, or the like.

A semiconductor wafer using a bulk substrate is a structure in which the charges generated at the substrate are received at the entire wafer, and therefore, the damage caused to the individual semiconductor elements is small. In contrast, a semiconductor wafer using the SOI substrate 11 is a structure in which the charges generated at the supporting substrate 11c concentrate at the semiconductor elements via the substrate contacts 15-1a, and therefore, the damage caused to the respective semiconductor elements is large.

Thus, by inserting the resistance element 13 between the supporting substrate 11c and the wire layer of the upper layer (e.g., the ground terminal GND2 for the substrate contact (see FIG. 2 or FIG. 4)) as in the present exemplary embodiment, even in cases in which a wire which electrically connects the substrate contact 15-1a and the ground end of the semiconductor element (the transistor 100) is formed, the charges generated at the supporting substrate 11c in the WP can be prevented from directly flowing-into the semiconductor element. As a result, poor resistance of the BOX layer at the semiconductor element and fluctuations in the characteristic of the semiconductor element can be prevented. Note that, in the present exemplary embodiment, it is preferable that the resistance value of the resistance element 13 be higher than the resistance value of the protecting circuit ESD. In this way, the protecting circuit ESD operating before charges flow-in to the supporting substrate 11c via the substrate contact 15-1a can be made to be even more reliable.

Note that the present exemplary embodiment gives an example of a case in which a polysilicon film is formed as the resistance element 13, but the present invention is not limited to the same. A diffusion region of a relatively low concentration may be formed at a portion of the SOI layer 11a, and this may be used as the resistance element. In this case, the resistance element is formed by providing a region, where the element-isolating insulating film 11A is not formed, at a portion of the SOI layer 11a, and doping therein impurities to an extent that the desired specific resistance is obtained.

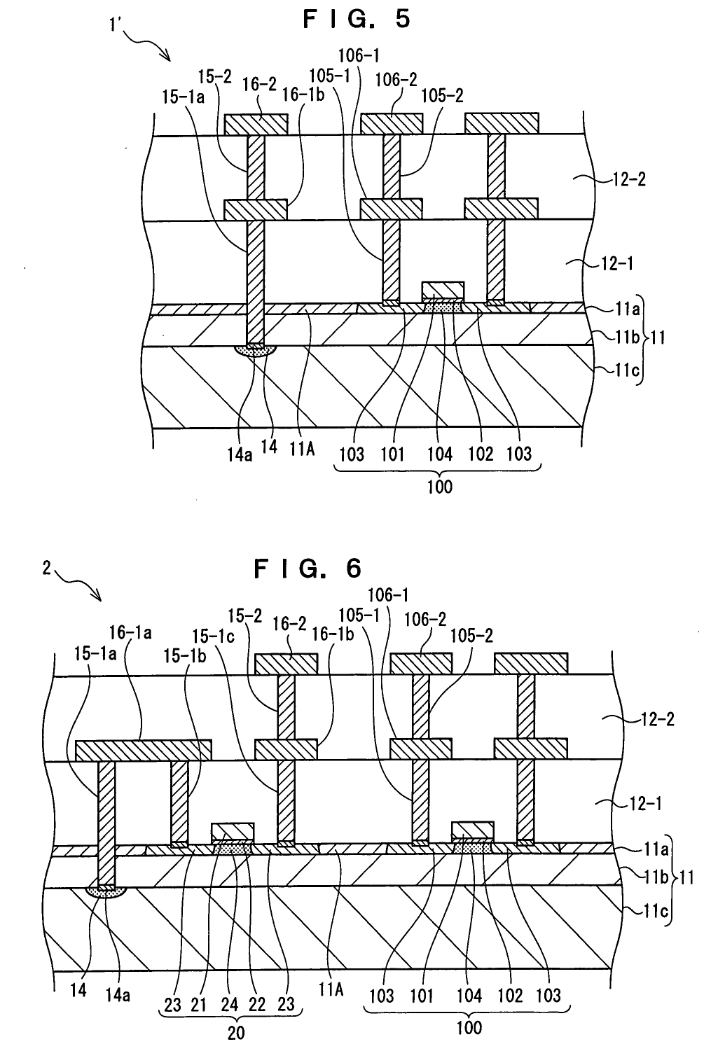

Further, the present exemplary embodiment gives the example of a case in which a polysilicon film is formed as the resistance element 13, but the present invention is not limited to the same. For example, as is the case with semiconductor device 1′ shown in FIG. 5, a resistance component of greater than or equal to about 2 kΩ for example can be formed as junction resistance between the ground terminal GND2 for the substrate contact and the supporting substrate 11c.

### Second Exemplary Embodiment

A second exemplary embodiment of the present invention will be described in detail next by using the drawings. Note that, in the following explanation, structures which are similar to those of the first exemplary embodiment are denoted by the same reference numerals, and detailed description thereof is omitted. Further, structures which are not mentioned specially are similar to those of the first exemplary embodiment.

### (Structure)

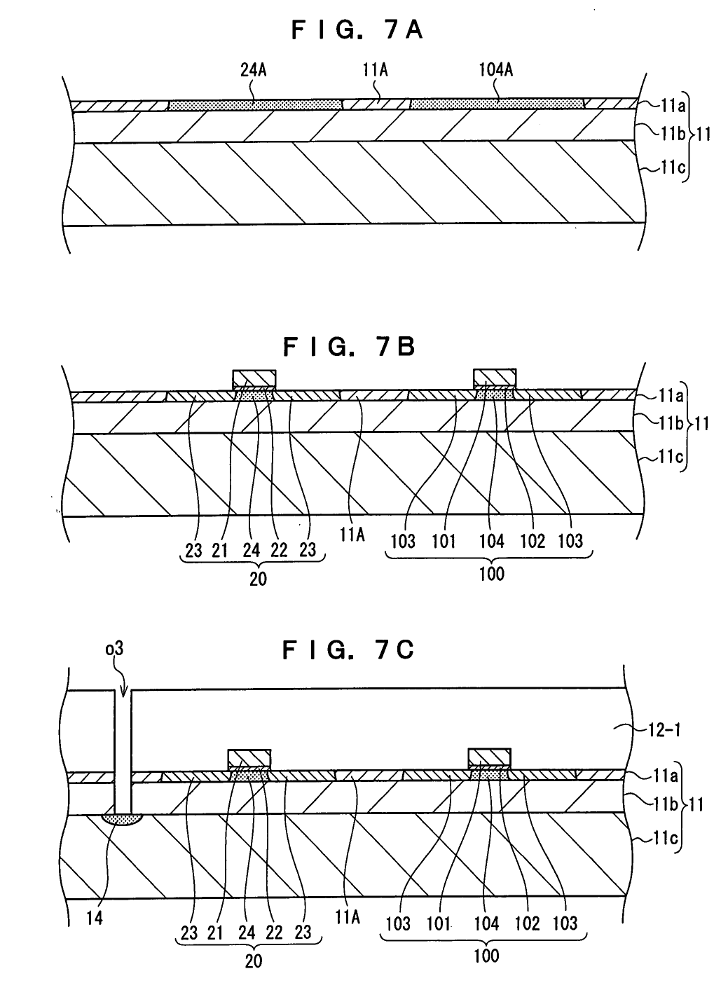

FIG. 6 is a cross-sectional view showing the layer structure of a semiconductor device 2 in accordance with the present exemplary embodiment. As shown in FIG. 6, the semiconductor device 2 has a structure in which, in a structure similar to the semiconductor device 1 of the first exemplary embodiment, the resistance element 13 is replaced by a depression-type MOS transistor (hereinafter, DMOS transistor) 20. Note that, because the other structures are similar to those of the semiconductor device 1 in accordance with the first exemplary embodiment, individual, detailed description thereof is omitted.

In the same way as the transistor 100, the DMOS transistor 20 in accordance with the present exemplary embodiment includes a pair of diffusion regions 23 which are formed at the active region of the SOI layer 11a, a body region 24 between the pair of diffusion regions 23, a gate insulating film 22 on the body region 24, and a gate electrode 21 on the gate insulating film 22. Accordingly, in the present exemplary embodiment, a region where the element-isolating insulating film 11A is not formed is provided at a portion of the field region at the SOI layer 11a, and the DMOS transistor 20 is formed thereat.

In the same way as the resistance element 13 in the first exemplary embodiment, at the DMOS transistor 20, one of the diffusion regions 23 is electrically connected to the via wire 15-1b, and is electrically connected to the supporting substrate 11c from this via wire 15-1b via the lowermost layer metal wire 16-1a and the substrate contact 15-1a. Further, similarly to the resistance element 13 in the first exemplary embodiment, the other diffusion region 23 is electrically connected to the lowermost layer metal wire 16-1b via the via wire 15-1c, and is electrically connected to the metal wire of the upper layer via this.

In this way, in the present exemplary embodiment, a DMOS transistor is used as the resistance element. Because the on resistance of a DMOS transistor generally is large as compared with polysilicon or silicon or the like of the same surface area, the surface area can be reduced by using the DMOS transistor 20 as a resistance element of a desired resistance value (e.g., greater than or equal to about 2 kΩ).

Note that the gate electrode 21 of the DMOS transistor 20 in accordance with the present exemplary embodiment may be in a floating state, or may be connected to, for example, a wire at the substrate contact 15-1a side.

### (Fabrication Method)

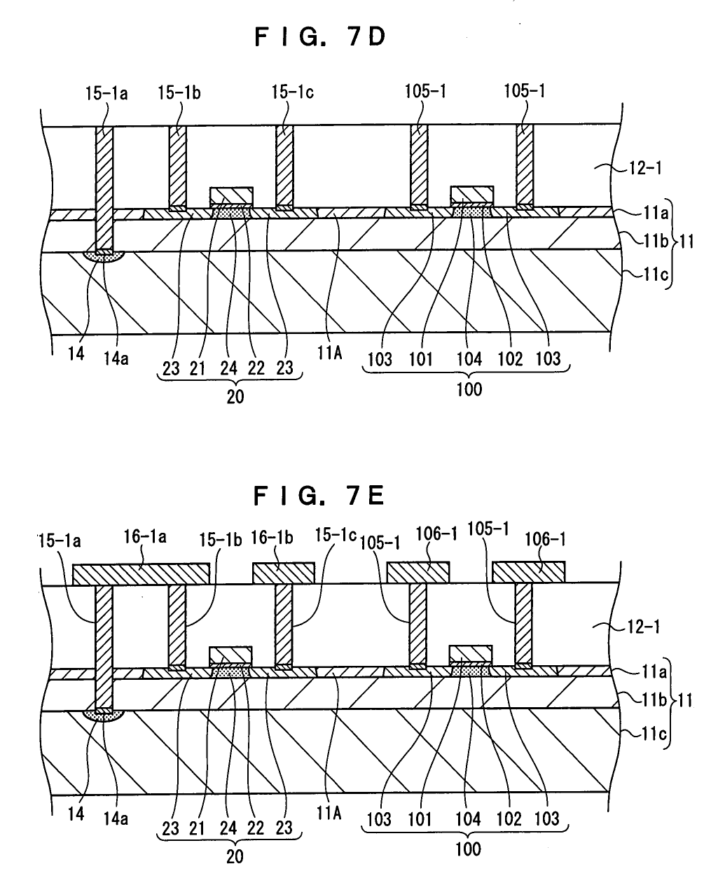

A method of fabricating the semiconductor device 2 in accordance with the present exemplary embodiment will be described in detail next by using the drawings. FIGS. 7A through 7E are process drawings showing a method of fabricating the semiconductor device 2 in accordance with the present exemplary embodiment.

In this method of fabrication, first, after the SOI substrate 11 is readied, the element-isolating insulating film 11A is formed at the SOI layer 11a by a process similar to the first exemplary embodiment. However, in the present exemplary embodiment, a region where the element-isolating insulating film 11A is not formed is provided at a portion of the field region. Next, in a process which is similar to the process described by using FIG. 3A in the first exemplary embodiment, predetermined impurities (e.g., boron ions) are injected into the active region and the region where the element-isolating insulating film 11A is not formed. In this way, as shown in FIG. 7A, the SOI layer 11a is sectioned into the field region, at which the element-isolating insulating film 11A is formed, and the active region 104A, in which impurities for threshold value adjustment are injected, and further, at a portion of the field region, there is formed an active region 24A in which impurities for threshold value adjustment are injected.

Next, the transistors 100 and 20 are respectively formed at the active regions 104A and 24A by using, for example, a process which is substantially similar to the process described by using FIG. 3B in the first exemplary embodiment. However, the resistance element 13 which is formed from the polysilicon film is not formed on the element-isolating insulating film 11A. In this way, a layer structure such as shown in FIG. 7B is obtained.

Next, by using, for example, a process which is substantially similar to the process described by using FIG. 3C in the first exemplary embodiment, the interlayer insulating film 12-1, which has the opening o3 at which the diffusion region 14 is formed at the contact portion, is formed. In this way, a layer structure such as shown in FIG. 7C is obtained.

Subsequently, the substrate contact 15-1a and the via wires 15-1b, 15-1c, and 105-1 are formed in the openings o3 and o4 of the interlayer insulating film 12-1, by using, for example, a process which is substantially similar to the process described by using FIG. 3D in the first exemplary embodiment. At this time, in the same way as in the first exemplary embodiment, the surface of the supporting substrate 11c which is exposed from the opening o3 and the surfaces of the diffusion regions 23 and 103 which are exposed from the openings o4 may respectively be salicided, before the substrate contact 15-1a and the via wires 15-1b, 15-1c and 105-1 are formed. In this way, a layer structure such as shown in FIG. 7D is obtained.

Next, in the same way as in the first exemplary embodiment, after a single-layer or multilayer metal film is accumulated on the interlayer insulating film 12-1, by patterning it by photolithography and etching, the lowermost layer metal wires 16-1a, 16-1b and 106-1 are formed on the interlayer insulating film 12-1 as shown in FIG. 7E.

Thereafter, one or more layers of the layers, which are formed from the interlayer insulating film 12-2 and the via wires 15-2 and 105-2 of the upper layer and the upper layer metal wires 16-2 and 106-1, are formed as needed. In this way, the semiconductor device 2 in accordance with the present exemplary embodiment, such as shown in FIG. 6, is fabricated.

As described above, in the present exemplary embodiment, by inserting the DMOS transistor 20, which serves as a resistance element, between the supporting substrate 11c and the wire layer of the upper layer (e.g., the ground terminal GND2 for the substrate contact (see FIG. 2 or FIG. 4 in the first exemplary embodiment)), effects which are similar to those of the first exemplary embodiment can be obtained.

Moreover, in accordance with the present exemplary embodiment, because the DMOS transistor 20, whose specific resistance is higher than that of a polysilicon film, is used as the resistance element, the surface area for forming the resistance element can be reduced. As a result, the semiconductor device 2 can be made to be compact.

Note that the present exemplary embodiment gives an example of a case in which the DMOS transistor 20 is formed as the resistance element. However, the present invention is not limited to the same, and, for example, the DMOS transistor 20 may be replaced with another transistor or a diode or the like.

### Third Exemplary Embodiment

A third exemplary embodiment of the present invention will be described in detail next by using the drawings. Note that, in the following explanation, structures which are similar to those of the first exemplary embodiment or the second exemplary embodiment are denoted by the same reference numerals, and detailed description thereof is omitted. Further, structures which are not mentioned specially are similar to those of the first exemplary embodiment or the second exemplary embodiment.

The present exemplary embodiment describes, as an example, a case in which a wire is formed which electrically connects the substrate contact 15-1a and the ground end of the semiconductor element (the transistor 100 in the present explanation). Note that, when describing the present exemplary embodiment hereinafter, structures of the semiconductor device 1 in accordance with the first exemplary embodiment are cited. However, the present invention is not limited to the same, and can similarly be applied to, for example, the semiconductor device 2 in accordance with the second exemplary embodiment.

### (Structure)

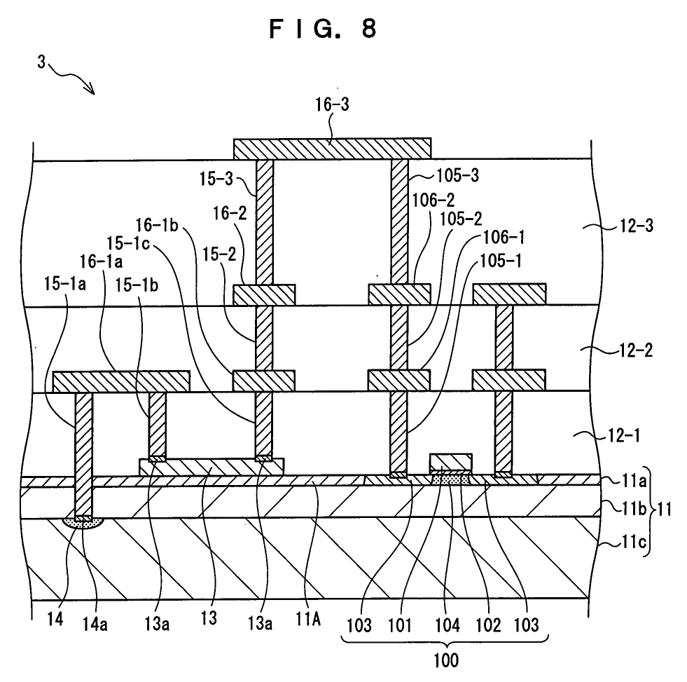

FIG. 8 is a cross-sectional view showing the layer structure of a semiconductor device 3 in accordance with the present exemplary embodiment. As shown in FIG. 8, the semiconductor device 3 has a structure similar to the semiconductor device 1 of the first exemplary embodiment, and in addition, has an interlayer insulating film 12-3, and via wires 15-2 and 105-2 and uppermost layer metal wires 16-3 and 106-3 which are formed at the interlayer insulating film 12-3.

In this structure, the interlayer insulating film 12-3 is an interlayer insulating film which is formed at the uppermost layer of the layer structure of the semiconductor device 3.

In the same way as the interlayer insulating films 12-1 and 12-2, for example, a silicon oxide film or a silicon nitride film or the like can be used as the interlayer insulating film 12-3. Further, the film thickness thereof can be made to be about 10,000 Å for example.

The uppermost layer metal wires 16-3 and 106-3 which are formed on the interlayer insulating film 12-3 can each be, for example, a metal film of titanium (Ti), aluminum (Al), copper (Cu), or the like, or a metal film formed from an alloy thereof. Further, a conductor film, such as a titanium nitride (TiN) film or a titanium aluminum nitride (TiAlN) film or the like, may be formed as an adhesion layer at the respective top and bottom surfaces of the metal wires 16-3 and 106-3.

The via wires 15-3 and 105-3 which pass through the interlayer insulating film 12-3 can be formed, for example, of a metal such as tungsten (W), copper (Cu), aluminum (Al) or the like, or of a polysilicon which is electrically conductive, or the like.

By connecting the substrate contact 15-1a and the ground end of the semiconductor element (the transistor 100) by the uppermost layer metal wire 16-3 in this way, the flowing-in, into the semiconductor element, of the charges generated at the supporting substrate 11c in the WP can be limited to only the process at the time of forming the uppermost layer metal wire 16-3. Namely, the flowing-in, into the semiconductor element, of the charges generated at the supporting substrate 11c in the WP can be kept to a minimum. As a result, poor resistance of the BOX layer at the semiconductor element and fluctuations in the characteristic of the semiconductor element can be kept to a minimum.

### (Fabrication Method)

A method of fabricating the semiconductor device 3 in accordance with the present exemplary embodiment will be described in detail next by using the drawings. However, in the present fabrication method, because the processes up through the formation of the upper layer metal wires 16-2 and 106-2 are similar to the first exemplary embodiment, detailed description thereof is omitted here.

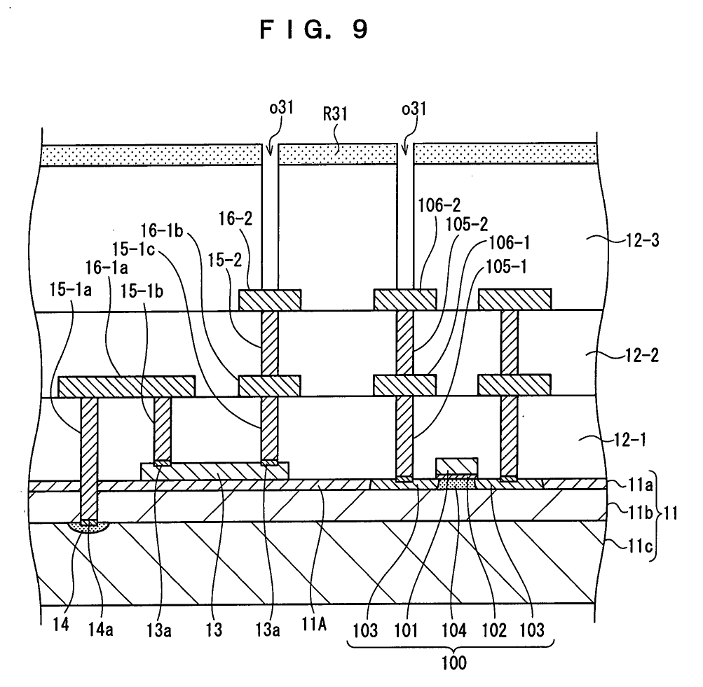

When the semiconductor device 3, which has a layer structure similar to that of the semiconductor device 1 shown in FIG. 1, is formed as described above, next, the interlayer insulating film 12-3, which is formed of a silicon oxide film of a film thickness of about 10,000 Å for example, is formed on the entire top surface of the interlayer insulating film 12-2 by using CVD for example. Then, by carrying out photolithography and etching, as shown in FIG. 9, openings o31, which pass through the interlayer insulating film 12-3 and respectively expose the upper layer metal wire 16-2, which is electrically connected to the resistance element 13, and the upper layer metal wire 106-2, which is electrically connected to the diffusion region 103 at the ground side of the transistor 100, are formed.

Then, by filling a conductor such as tungsten (W) or the like for example into the openings o31 of the interlayer insulating film 12-3 by using sputtering for example, the via wires 15-3 and 105-3 are formed. At this time, the surfaces of the upper layer metal wires 16-2 and 106-2 which are exposed by the respective openings o31 may be salicided, before the via wires 15-3 and 105-3 are formed.

Next, after a single-layer or multilayer metal film is accumulated on the interlayer insulating film 12-3, by patterning it by photolithography and etching, the uppermost layer metal wire 16-3, which electrically connects the via wire 15-3 and the via wire 105-3, is formed. In this way, as shown in FIG. 8, the semiconductor device 3, in which the substrate contact 15-1a and the ground end of the transistor 100 are electrically connected at the uppermost layer, is fabricated.

As described above, in the present exemplary embodiment, by inserting the resistance element 13 between the supporting substrate 11c and the wire layer of the upper layer (e.g., the ground terminal GND2 for the substrate contact (see FIG. 2 or FIG. 4 in the first exemplary embodiment)), effects which are similar to those of the first exemplary embodiment can be obtained.

Further, in the present exemplary embodiment, because the substrate contact 15-1a and the ground end of the semiconductor element (the transistor 100) are connected at the metal wire of the uppermost layer (the uppermost layer metal wire 16-3), the flowing-in, into the semiconductor element, of the charges generated at the supporting substrate 11c in the WP can be limited to only the process at the time of forming the uppermost layer metal wire 16-3. Namely, the flowing-in, into the semiconductor element, of the charges generated at the supporting substrate 11c in the WP can be kept to a minimum. As a result, poor resistance of the BOX layer at the semiconductor element and fluctuations in the characteristic of the semiconductor element can be kept to a minimum.

The above-described first exemplary embodiment through third exemplary embodiment are merely examples for implementing the present invention, and the present invention is not to be limited to these examples. Modifying these exemplary embodiments variously is within the scope of the present invention. Further, it should be evident from the above description that various other exemplary embodiments are possible within the scope of the present invention.

What is claimed is:

1. A semiconductor device comprising:
an SOI substrate including a supporting substrate, an insulating film on the supporting substrate, and a semiconductor layer on the insulating film;
an element-isolating insulating film sectioning the semiconductor layer into an element forming region and an element isolating region;
a resistance element formed at the element isolating region;
one or more layers of an interlayer insulating film formed on the SOI substrate;
a first terminal formed on the interlayer insulating film;
a substrate contact passing through the element-isolating insulating film and the insulating film, and electrically connected to the supporting substrate;
a first wire electrically connecting the substrate contact and the resistance element; and
a second wire electrically connecting the resistance element and the first terminal.

2. The semiconductor device of claim 1, wherein the resistance element is a polysilicon film.

3. The semiconductor device of claim 2, wherein the polysilicon film is formed on the element-isolating insulating film.

4. The semiconductor device of claim 1, wherein the resistance element is a transistor or a diffusion region formed at the semiconductor layer which remains at a portion of the element isolating region.

5. The semiconductor device of claim 1, wherein a resistance value of the resistance element is greater than or equal to 2 kΩ.

6. A semiconductor device comprising:
an SOI substrate including a supporting substrate, an insulating film on the supporting substrate, and a semiconductor layer on the insulating film;
an element-isolating insulating film sectioning the semiconductor layer into an element forming region and an element isolating region;
a resistance element formed at the element isolating region;
one or more layers of an interlayer insulating film formed on the SOI substrate;
a first terminal formed on the interlayer insulating film;
a substrate contact passing through the element-isolating insulating film and the insulating film, and electrically connected to the supporting substrate, a junction resistance of the substrate contact and the supporting substrate being greater than or equal to 2 kΩ;
a first wire electrically connecting the substrate contact and the resistance element; and
a second wire electrically connecting the resistance element and the first terminal.

7. The semiconductor device of claim 1, further comprising:
a semiconductor element formed at the semiconductor layer;
a second terminal formed on the interlayer insulating film;
a third wire electrically connecting the second terminal and the semiconductor element; and
a fourth wire electrically connecting the second wire and a region from the resistance element to the first terminal.

8. The semiconductor device of claim 7, further comprising:
a third terminal formed on the interlayer insulating film;
a fifth wire electrically connecting the third terminal and the semiconductor element; and
a protecting circuit connected in parallel to the semiconductor element, between the second terminal and the third terminal.

9. The semiconductor device of claim 8, wherein the third wire is a wire formed on the interlayer insulating film of an uppermost layer among the one or more layers of the interlayer insulating film.

10. The semiconductor device of claim 1, further comprising:
a third terminal formed on the interlayer insulating film and adjacent to the first terminal,
wherein the resistance element is formed between the first terminal and the third terminal.

11. A method of fabricating a semiconductor device comprising:
preparing an SOI substrate which includes a supporting substrate, an insulating film on the supporting substrate, and a semiconductor layer on the insulating film;
sectioning the semiconductor layer into an element forming region and an element isolating region by forming an element-isolating insulating film at the semiconductor layer;
forming a first transistor at the element forming region, and forming a resistance element at the element isolating region;
forming an interlayer insulating film on the semiconductor layer at which the first transistor and the resistance element are formed;
forming a substrate contact which passes through the interlayer insulating film, the element-isolating insulating film and the insulating film, and which is electrically connected to the supporting substrate; and
respectively forming a first wire, which electrically connects the substrate contact and the resistance element, and a second wire, which electrically connects the resistance element and the first transistor.

12. The method of fabricating a semiconductor device of claim 11, wherein the resistance element is a polysilicon film formed on the element-isolating insulating film.

13. The method of fabricating a semiconductor device of claim 11, wherein the element isolating region has, at a portion thereof, a first region at which the element-isolating insulating film is not formed, and
the resistance element is a second transistor or an impurity diffusion region formed at the first region.

14. The method of fabricating a semiconductor device of claim 11, wherein a plurality of layers of the interlayer insulating film are formed, and
the second wire electrically connects the resistance element and the first transistor via a wire which is formed on the interlayer insulating film of an uppermost layer among the plurality of interlayer insulating films.
